(19) United States
(12) Patent Application Publication
(10) Pub. No.: US 2001/0006757 A1
(43) Pub. Date: Jul. 5, 2001

(54) RADIANT RAY-SENSITIVE LITHOGRAPHIC PRINTING PLATE PRECURSOR

(75) Inventors: KIYOTAKA FUKINO, SHIZUOKA (JP); KOICHI KAWAMURA, SHIZUOKA (JP); KAZUO MAEMOTO, SHIZUOKA (JP); SEISHI KASAI, SHIZUOKA (JP)

Correspondence Address: BURNS DOANE SWECKER & MATHIS L L P, POST OFFICE BOX 1404, ALEXANDRIA, VA, 22313-1404, US

(73) Assignee: Kiyotaka Fukino

(21) Appl. No.: 09/263,502

(22) Filed: Mar. 8, 1999

(30) Foreign Application Priority Data
Mar. 9, 1998 (JP) 10-56974
Aug. 26, 1998 (JP) 10-240536

(51) Int. Cl. G03F 7/004; G03F 7/26

(52) U.S. Cl. 430/270.1; 430/302; 430/303

(57) ABSTRACT

A radiant ray-sensitive lithographic printing plate precursor which comprises (a) material or material series which absorbs radiant rays, converts the absorbed radiant rays to heat, and enters into a self-exothermic reaction by the heat, and (b) material or material series which causes a chemical change or a physical change by the reaction heat generated as a result of the self-exothermic reaction.

### FIELD OF THE INVENTION

The present invention relates to a lithographic printing plate precursor. Particularly, the present invention relates to a lithographic printing plate precursor from which a printing plate can be directly obtained by plate-making after image information has been, recorded by irradiation of heat mode radiant ray such as operation of an infrared laser etc. based on digital signals or by heat transfer via a thermal head without requiring additional operations.

### BACKGROUND OF THE INVENTION

The following methods are conventionally known as methods of directly processing a printing plate from digitalized image data without a lith film: (1) a method by electrophotography, (2) a method of using a high sensitivity photopolymer capable of writing with a laser system of comparatively small output which emits blue or green light, (3) a method of using silver salt or a composite system of silver salt and other systems, and (4) a method in which acid is generated by heat mode laser exposure and a thermosetting image is formed by post-heating by making the generated acid as a catalyst.

These methods are not necessarily sufficiently satisfactory under the present conditions, although they are very useful in view of the rationalization of the printing process. For example, in the above method (1) wherein an electrophotographic method is used, image-forming processes such as electric charge, exposure and development are complicated and the apparatus is intricate and large-scaled. In method (2) of using a photopolymer, since a high sensitivity printing plate is used, handling of a printing plate in a bright room is difficult. In method (3) of using silver salt, the treatment is complicated and there is such a drawback as silver is contained in a waste solution. Method (4) requires post-heating and succeeding development, therefore, this method is also accompanied by complicated treatment.

Further, the production of printing plates includes various processes after an exposure process such as a wet development process for imagewise removing a recording layer provided on a support surface, a washing process of a development processed printing plate with water, and a post treatment process for processing the plate with a rinsing solution containing a surfactant, gum arabic, and a desensitizing solution containing a starch derivative.

On the other hand, in the plate-making and printing industries in recent years, rationalization of plate-making operations has been advanced, and a printing plate precursor which does not require the above-described complicated wet development process and can be used in printing as it is after exposure is demanded.

As a printing plate precursor which does not require a development process after image exposure, for example, a lithographic printing plate comprising a support having laminated thereon a photosensitive hydrophilic layer and a photosensitive hydrophobic layer whose hardening or insolubilization is accelerated at the exposure region is disclosed in U.S. Pat. No. 5,258,263. However, this is a so-called development on a printing machine type plate whose non-exposed part of the photosensitive layer is removed during the printing process, and the plate of this type has such a drawback as a fountain solution and printing ink are contaminated.

As a lithographic printing plate precursor which does not require a wet development process after image formation, printing plates comprising a silicone layer and a laser heat-sensitive layer as an underlayer are disclosed in U.S. Pat. Nos. 5,353,705 and 5,379,698. These plates do not require wet development but, alternatively, rubbing or a process by specific rollers for completing the removal of the silicone layer by laser abrasion is required, therefore, the process is complicated.

There are disclosed in JP-A-5-77574, JP-A-4-125189 (the term“JP-A” as used herein means an “unexamined published Japanese patent application”), U.S. Pat. No. 5,187,047 and JP-A-62-195646 techniques of forming a lithographic printing plate precursor which does not require a development process by converting the hydrophilicity (i.e., the hydrophilic property) of the surface of a plate by thermal writing using a film of sulfonated polyolefins. In these systems, an image is formed by desulfonating the sulfone group on the surface of a plate by thermal writing, therefore, a development process is unnecessary, but there is such a problem as noxious gas is generated at writing.

A system requiring no development, that is, a lithographic printing plate precursor comprising a polymer having an acid-sensitive group as a side chain and a light-acid generating agent in combination, is proposed in U.S. Pat. Nos. 5,102,771 and 5,225,316. However, as the acid generated in this lithographic printing plate precursor is a carboxylic acid, the hydrophilicity thereof is restricted, therefore, durability of the printing plate and sharpness of the printed image are deteriorated.

A lithographic printing plate precursor comprising a polymer which generates carboxylic acid by the action of heat and acid and an infrared ray-absorbing dye is disclosed in JP-A-7-186562 (corresponding to European Patent 652483). However, there arises such a problem as a lithographic printing plate using this lithographic printing plate precursor causes contamination under a severe printing condition.

### SUMMARY OF THE INVENTION

The present invention has been done in view of the fact that the above-described conventionally proposed various methods of a photomechanical process to make capable of directly making printing plates from printing plate precursors do not have satisfactory print quality and working simplicity. Accordingly, a first object of the present invention is to provide a lithographic printing plate precursor on which an image of high sensitivity can be recorded by heating or by heat generated by light/heat conversion and which requires no wet development and no special treatment such as rubbing etc. after an image has been recorded.

A second object of the present invention is to provide a novel means to separate an image part from a non-image part necessary for the first object.

A third object of the present invention is to provide a lithographic printing plate precursor which is particularly effective for the first object by using a polymer compound having a functional group which generates a sulfonic acid by heating.

The present inventors thought that the achievement of the objects of the present invention was restricted by the fact that the generation of heat due to the absorption of radiant rays is limited during irradiation. As a result of eager examination concerning the means for overcoming thereof, we found that the objects of the present invention could be achieved by the following constitution, thus the present invention has been completed.

Accordingly, the above objects of the present invention have been attained by the following means.

1. A radiant ray-sensitive lithographic printing plate precursor which comprises (a) a material or a material series which absorbs radiant rays, converts the absorbed radiant rays to heat, and enters into a self-exothermic reaction by the heat, and (b) a material or a material series which causes a chemical change or a physical change by the reaction heat generated as a result of the self-exothermic reaction.

2. The radiant ray-sensitive lithographic printing plate precursor as described in the above item 1, wherein the material or the material series which absorbs radiant rays, converts the absorbed radiant rays to heat, and enters into a self-exothermic reaction by the heat is a metal powder or a metal compound powder.

3. A radiant ray-sensitive lithographic printing plate precursor which comprises a support having provided thereon an image-recording layer containing (a) a material or a material series which absorbs radiant rays, converts the absorbed radiant rays to heat, and enters into a self-exothermic reaction by the heat (hereinafter referred to as merely “a self-exothermic reactant”), and (b) a resin having a siloxane bond and a silanol group.

4. The radiant ray-sensitive lithographic printing plate precursor as described in the above item 3, wherein the support is hydrophobic.

5. The radiant ray-sensitive lithographic printing plate precursor as described in the above item 3, wherein the material or material series which absorbs radiant rays, converts the absorbed radiant rays to heat, and enters into a self-exothermic reaction by the heat is metal or a metal compound, and the image-recording layer further contains anatase-type titanium oxide fine particles.

6. The radiant ray-sensitive lithographic printing plate precursor as described in the above item 1, wherein the chemical change or the physical change caused by the reaction heat generated as a result of the self-exothermic reaction is the change from hydrophobicity to hydrophilicity.

7. The radiant ray-sensitive lithographic printing plate precursor as described in the above item 1, wherein the material or the material series which causes the chemical change or the physical change by the reaction heat generated as a result of the self-exothermic reaction is a polymer compound having a functional group which generates a sulfonic acid by heating.

8. The radiant ray-sensitive lithographic printing plate precursor as described in the above item 7, wherein the functional group which generates a sulfonic acid by heating is at least one compound represented by formula (1), (2) or (3):

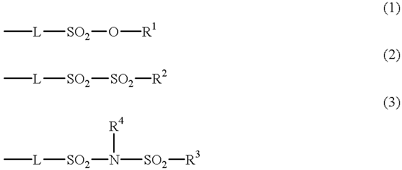

wherein L represents an organic group comprising polyvalent nonmetal atoms necessary for linking a functional group represented by formula (1), (2) or (3) to the polymer skeleton; R¹ represents a substituted or unsubstituted aryl group, a substituted or unsubstituted alkyl group, or a cyclic imido group; R² and R³ each represents a substituted or unsubstituted aryl group, or a substituted or unsubstituted alkyl group; R⁴ represents a substituted or unsubstituted aryl group, a substituted or unsubstituted alkyl group, or —SO₂—R⁵; and R⁵ represents a substituted or unsubstituted aryl group, or a substituted or unsubstituted alkyl group.

9. The radiant ray-sensitive lithographic printing plate precursor as described in the above item 8, wherein R¹ of the functional group represented by formula (1) which generates a sulfonic acid by heating is a secondary alkyl group represented by formula (4):

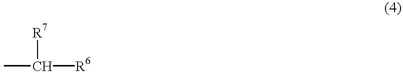

wherein R⁶ and R⁷ each represents a substituted or unsubstituted alkyl group, and R⁶ and R⁷ may form a ring together with the secondary carbon atom (CH) to which they are bonded.

10. The radiant ray-sensitive lithographic printing plate precursor as described in the above item 9, wherein the secondary alkyl group represented by formula (4) is a secondary alkyl group represented by at least one formula selected from the group consisting of the following formulae:

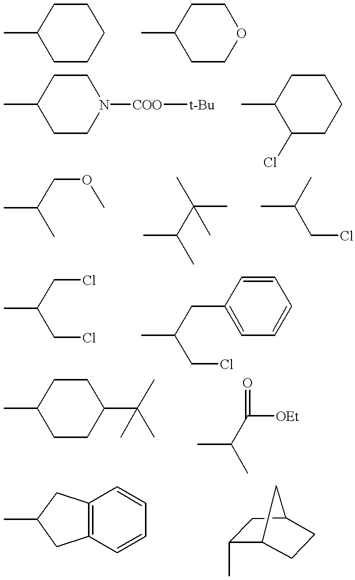

11. A lithographic printing method which comprises conducting image recording by imagewise irradiation of radiant rays or imagewise heat transfer by means of a thermal head on the radiant ray-sensitive lithographic printing plate precursor which comprises (a) a material or a material series which absorbs radiant rays, converts the absorbed radiant rays to heat, and enters into a self-exothermic reaction by the heat, and (b) a material or a material series which causes a chemical change or a physical change by the reaction heat generated as a result of the self-exothermic reaction, setting this image recorded plate on a lithographic printing machine and printing without subjecting the plate to a wet development process.

### DETAILED DESCRIPTION OF THE INVENTION

The cardinal and novel point of the present invention is, as described above, that the material sensitive to radiant rays (hereinafter sometimes referred to simply “light” representing “radiant rays”) or heat is not merely a light/heat conversion material which absorbs light and converts it to heat and this is a material which enters into a self-exothermic reaction with making the converted heat as a trigger. The quantity of heat energy converted by light/heat conversion mechanism of course does not exceed the quantity of the original light energy. Accordingly, in many cases, as the heat energy itself is small, or as the supply of heat is restricted in the course of the time when the exposure of radiant rays is being conducted, the heat energy is in general insufficient to cause a chemical reaction or a physical change necessary for image recording. The present inventors noticed this point and introduced a novel technical idea, as a countermeasure to this problem, such that it is effective to incorporate into a printing plate precursor a mechanism in which a self-exothermic reaction is induced by the heat generated by light/heat conversion, and a chemical or physical change continues by the heat generated by the self-exothermic reaction even after the completion of irradiation of radiant rays. Thus, the present invention has been achieved.

In the present invention, the quantity of the heat obtained by light/heat conversion is sufficient to cause a rise in temperature capable of beginning a chemical or a physical change, and the succeeding continuation of change can be effected by the maintenance of the self-exothermic reaction. Therefore, as instantaneous big heat energy is not required, the increase of sensitivity is easily attained, and the lowering of resolving power as is often encountered in the case of depending solely upon light/heat conversion can be prevented.

A self-exothermic reaction which is the fundamental of the radiant ray-sensitive lithographic printing plate precursor according to the present invention is further described prior to describing the execution mode of the present invention in detail.

In the present invention, a self-exothermic reaction means an exothermic chemical reaction which begins with making the heat energy generated by light/heat conversion reaction starting energy. The reaction heat discharged by this chemical reaction maintains it's own chemical reaction and thereby a chemical or physical change to separate an image part from a non-image part is brought about. That is, the heat generated by light/heat conversion gives energy as a trigger capable of getting over the active energy of the succeeding exothermic reaction to thereby obtain further larger heat energy from the self-exothermic type chemical reaction. Accordingly, this is a kind of energy amplification to radiant ray energy for image exposure. For example, when metal iron is used as a self-exothermic reaction material, this heat energy is 400 kJ per mol.

Whether this self-exothermic reaction occurs or not can be easily confirmed by differential thermo balance (TG/DTA) (thermogravimetry/differential thermal analysis). When a self-exothermic reactant is inserted into a differential thermobalance and the temperature is raised at a constant rate, an exothermic peak appears at a certain temperature, by which the fact of an exothermic reaction having occurred can be confirmed. When an oxidation reaction of metal or lower metallic oxide is used as a self-exothermic reaction, the weight increase is also observed in the thermobalance as well as the appearance of the exothermic peak. As is the repetition of the above, by the use of the energy by a self-exothermic reaction in addition to a light/heat conversion mechanism, more heat energy per a unit radiant ray amount than that conventionally used can be used and moreover continuously, as a result, sensitivity can be improved.

The heat energy generated by a self-exothermic reaction is used to cause a chemical change or a physical change to separate an image part from a non-image part. This chemical or physical change can be used in any conventionally known separating means by heat in principle. Accordingly, the selection of the means is not limited to those described in the present specification and can be selected from the broad range.

The present invention will be described in detail below.

(a) A material or a material series which absorbs radiant rays, converts the absorbed radiant rays to heat, and enters into a self-exothermic reaction by the heat, and (b) a material or a material series which causes a chemical change or a physical change by the reaction heat generated as a result of the self-exothermic reaction, which are fundamentals of the present invention, are described in the first place.

First, a material or a material series (a) which can be applied to the present invention may be any material or material series so long as it can absorb radiant rays and convert them to heat. Examples of such materials or material series include the following but the present invention is not construed as being limited thereto.

(1) A system which starts an self-exothermic reaction by the contact of self-exothermic reaction components with each other in a liquid phase generated by the melting action caused by the heat generated by light/heat conversion:

### EXAMPLES

A series of (i) a material capable of light/heat conversion and low melting point dispersed particles (e.g., wax particles) containing reaction component B which reacts with reaction component A, and (ii) a dispersion medium containing reaction component A. When the light energy given by radiant ray irradiation dissolves low melting point dispersed particles by light/heat conversion, reaction component A starts to contact with reaction component B in a molten liquid phase, a self-exothermic reaction continues without irradiation of radiant rays thereafter, and the separation of an image part from a non-image part progresses. The light/heat conversion material and reaction component B may be the same (e.g., a metal powder) or different series comprising other materials.

The following materials or material series can be exemplified as the analogous examples.

a. A series of (i) solid acid having a low melting point (e.g., a higher fatty acid) containing a light/heat conversion material, and (ii) a basic material.

b. A series of (i) silver salt having a low melting point (e.g., silver behenate, in particular, silver behenate onto which a spectral sensitizing dye is adsorbed) containing a light/heat conversion material, and (ii) a reducing material (a reducing agent for heat development).

c. A series of (i) wax containing a metal fine powder such as silver fine powder, and (ii) the oxidant of that metal.

(2) A system in which the heat energy converted from light energy by radiant ray irradiation gets over the activated energy of the self-exothermic reaction thereby the self-exothermic reaction starts.

Systems which do not react on each other at room temperature even if contacted to each other but begin to react on each other at high temperature correspond to this case. For example, system which perform an oxidation reaction with the oxygen of the air correspond to this case. The following materials or material series can be exemplified as such examples.

a. The case in which separation of an image part from a non-image part progresses by the air oxidation (self-exothermic reaction) of a metal solid fine powder which is also a light/heat conversion material.

b. The case in which a heat crosslinking reaction progresses by a self-exothermic reaction in the above item a.

c. The case in which a heat development reaction progresses by a self-exothermic reaction in the above item a.

d. The case in which a pyrolytic reaction progresses by a self-exothermic reaction in the above item a.

e. The case in which the heat generated by a photolysis of a photolytic compound (e.g., an azide compound) advances an exothermic self-decomposition reaction (self-exothermic reaction).

f. The case in which a self-exothermic reaction is a neutralizing reaction of acid/alkali in the above item e.

Besides the above, a chemical reaction such as a dehydration condensation reaction (of silanol groups), an esterification reaction, a hardening reaction, a polymerization reaction, or a depolymerization reaction, and a reaction to cause a physical change such as abrasion or film softening can be used in a self-exothermic reaction or accompanying separating reaction of an image part and a non-image part.

Further, images to be formed may be a negative image or a positive image according to materials or material series which are used.

Among the above-described materials or material series (a) which absorb radiant rays, convert the absorbed radiant rays to heat, and enter into a self-exothermic reaction by the heat, particularly preferred materials are metal powders or metal compound powder, and they constitute self-exothermic reaction system with the oxygen of the air. Specifically, compounds such as a metal, a metallic oxide, a metallic nitride, a metallic sulfide, a metallic carbide, etc.

Examples of metals include Mg, Al, Si, Ti, V, Cr, Mn, Fe, Co, Ni, Cu, Zn, Ga, Ge, Y, Zr, Nb, Mo, Tc, Ru, Pd, Ag, Cd, In, Sn, Sb, Hf, Ta, W, Re, Os, Ir, Pt, Au, Pb, etc. Of these metals, those which can particularly easily cause an exothermic reaction such as an oxidation reaction by heat energy are preferred, specifically, Al, Si, Ti, V, Cr, Mn, Fe, Co, Ni, Cu, Zn, Y, Zr, Mo, Ag, In, Sn, and W. Further, Fe, Co, Ni, Cr, Ti, and Zr are preferred in view of having high absorption rate of radiant rays and large self-exothermic reaction heat energy.

These metals can be used alone or two or more in combination. Constitutions comprising metals with metallic oxides, metallic nitrides, metallic sulfides, metallic carbides can also be used. A metal alone rather gives large self-exothermic reaction heat energy such as oxidation etc. but handling in the air is complicated and a metal alone is attended with danger of spontaneous combustion when comes in contact with the air. Therefore, several nanometers in thickness from the surface is preferably covered with oxides, nitrides, sulfides or carbides.

These compounds may be particles or thin films such as deposited films, but particles are preferred when organic compounds are used in combination. The particle size is generally 10 μM or less, preferably from 0.005 to 5 μm, and more preferably from 0.01 to 3 μm. When the particle size is 0.01 μm or less, dispersion of particles are difficult and when the particle size is more than 10 μm, definition of printed matters is deteriorated.

The content of these particles in an image-forming layer is preferably from 2 to 95% by weight, more preferably from 5 to 90% by weight. If the content is less than 2% by weight, calorific power becomes short, and when the content is more than 95% by weight, the film strength is lowered.

Further, the transmission density of an image-forming layer is preferably from 0.3 to 3.0 measured based upon the International Standardization Organization IS05-3 and ISO5-4. If the transmission density exceeds 3.0, unevenness of radiant ray strength in the thickness direction of an image layer is caused due to the attenuation of radiant rays, as a result, aberration is liable to occur. While when it is less than 0.3, radiant ray energy is not sufficiently absorbed, as a result, the heat energy obtained by light/heat conversion is often insufficient.

Of the above-described metal fine powders, iron (fine) powders are preferably used. Any iron powders are preferably used. Above all, iron alloy (fine) powders containing α-Fe as a main Component are preferred. These powders may contain, in addition to the prescribed atoms, the following atoms, e.g., Al, Si, S, Sc, Ca, Ti, V, Cr, Cu, Y, Mo, Rh, Pd, Ag, Sn, Sb, Te, Ba, Ta, W, Re, Au, Hg, Pb, Bi, La, Ce, Pr, Nd, P, Co, Mn, Zn, Ni, Sr and B. In particular, it is preferred to contain at least one of Al, Si, Ca, Y, Ba, La, Nd, Co, Ni and B, in addition to α-Fe, and more preferably at least one of Co, Y and Al in addition to α-Fe. The content of Co is preferably from 0 to 40 atomic %, more preferably from 15 to 35 atomic %, and most preferably from 20 to 35 atomic %, the content of Y is preferably from 1.5 to 12 atomic %, more preferably from 3 to 10 atomic %, and most preferably from 4 to 9 atomic %, the content of Al is preferably from 1.5 to 12 atomic %, more preferably from 3 to 10 atomic %, and most preferably from 4 to 9 atomic %, each based on Fe. Iron alloy fine powders may contain a small amount of a hydroxide or an oxide. Specific examples thereof are disclosed in JP-B-44-14090 (the term “JP-B” as used herein means an “examined Japanese patent publication”), JP-B-45-18372, JP-B-47-22062, JP-B-47-22513, JP-B-46-28466, JP-B-46-38755, JP-B-47-4286, JP-B-47-12422, JP-B-47-17284, JP-B-47-18509, JP-B-47-18573, JP-B-39-10307, JP-B-46-39639, U.S. Pat. Nos. 3,026,215, 3,031,341, 3,100,194, 3,242,005, and 3,389,014.

Iron alloy fine powders can be prepared by well-known processes, such as a method comprising reducing a composite organic acid salt (e.g., organic acid salt comprising mainly an oxalate) with a reducing gas (e.g., hydrogen); a method comprising reducing iron oxide with a reducing gas (e.g., hydrogen), to obtain Fe or Fe—Co particles; a method comprising pyrolysis of a metal carbonyl compound; a method comprising adding to an aqueous solution of a ferromagnetic metal a reducing agent (e.g., sodium boronhydride, hypophosphite, or hydrazine), to conduct reduction; and a method comprising evaporating a metal in a low pressure inert gas to obtain a fine powder. The thus-obtained ferromagnetic alloy powders which are subjected to well-known gradual oxidization treatment can be used in the present invention, e.g., a method comprising immersing powders in an organic solvent, then drying; a method comprising immersing powders in an organic solvent, then charging an oxygen-containing gas to form oxide films on the surfaces thereof and drying; and a method comprising forming oxide films on the surfaces of the powders by regulating partial pressure of an oxygen gas and an inert gas without using an organic solvent.

Iron alloy powders which can be preferably used in the present invention have a specific surface area (S_{BET}) as measured by the BET method of from 20 to 80 m²/g, preferably from 40 to 60 m²/g. When S_{BET} is less than 20 m²/g, surface property is deteriorated, and when SBPT is more than 80 m²/g, good dispersibility is obtained with difficulty, which is not preferred. Iron alloy (fine) powders according to the present invention have a crystallite size of generally from 80 to 350 Å, preferably from100 to 250 Å, and more preferably from 140 to 200 Å. The length of a long axis of iron alloy (fine) powders is generally from 0.02 to 0.25 μm, preferably from 0.05 to 0.15 μm, and more preferably from 0.06 to 0.1 μm. Iron alloy (fine) powders preferably have an a cicular ratio of from 3 to 15, more preferably from 5 to 12.

When the material or material series described in (a) above is a metallic oxide, there are a case in which the metallic oxide per se conducts light/heat conversion and gives a reaction starting energy to a reactant series which enters into a self-exothermic reaction, and a case in which the metallic oxide itself is a lower oxide of a polyvalent metal and is a light/heat conversion material and, at the same time, is a self-exothermic type air oxidation reactant, similarly to the above metal powders. The former is a light-absorptive heavy metallic oxide, and oxides of Fe, Co, and Ni can be exemplified as examples thereof.

Examples of the latter case include ferrous oxide, triiron tetroxide, titanium monoxide, stannous oxide, and chromium(II) oxide. The latter, i.e., lower metal licoxides, are particularly preferred, and among these, ferrous oxide, triiron tetroxide, and titanium monoxide are preferred.

When the material or material series described in (a) above is a metallic nitride, preferred metallic nitrides are azide compounds of metals, in particular, azide compounds of copper, silver and tin are preferred. These azide compounds generate heat by photolysis and cause the succeeding pyrolytic reaction.

When the material or material series described in (a) above is a metallic sulfide, preferred metallic sulfides are heavy metallic sulfides such as radiant ray-absorptive transition metals. Preferred metallic sulfides among these are silver sulfide, ferrous sulfide, and cobalt sulfide. In these cases, material series comprising simple sulfur and a self-exothermic reactant such as alkaline carbonate in coexistence are used.

Further, as is described for making sure, techniques of series of light/heat conversion type image-forming materials as disclosed in JP-A-9-15849, JP-A-9-300816, JP-A-8-337053, JP-A-8-337054 and JP-A-8-337055 relate to image-forming materials of forming images by bringing about abrasion by absorbed laser beams (local breakage of the light-exposed part), and there are disclosed in these patents that metal fine powders containing iron powders such as magnetic powders are used as a coloring agent and a light/heat conversion material. However, the use of self-exothermic reaction disclosed in the specification of the present invention is not suggested in these patents at all, moreover, the transmission density used in the above patents is 3 or more which is inconvenient for exhibiting self-exothermic reaction. Therefore, the technical concept of the present invention is not included in these patents.

Carbon black is included in the above-described self-exothermic reactant but as carbon black is hydrophobic, when it is contained in mixture in the image-recording layer according to the present invention comprising a hydrophilic siloxane series resin, the hydrophilicity of the image-recording layer is deteriorated. On the other hand, since iron powder, which is suitable as the self-exothermic reactant contained in the image-recording layer of the lithographic printing plate precursor of the present invention, is surface-covered with alumina or silica, it is hydrophilic from the first. Accordingly, when iron powder is contained in mixture in the image-recording layer comprising a hydrophilic siloxane series resin, the hydrophilicity of the image-recording layer is not deteriorated.

Further, carbon black becomes Co₂ gas when oxidized but iron powder becomes Fe₂O₃ and solid as it is.

In addition, iron powder causes an oxidation reaction at about 120° C., but until comparatively high energy is given, e.g., about 450° C., carbon black does not cause an oxidation reaction.

From the above, iron powder is superior to carbon black as the self-exothermic reactant to be contained in the image-recording layer of the lithographic printing plate precursor of the present invention.

Explanation regarding materials or material series (a) which absorb radiant rays, convert the absorbed radiant rays to heat, and enter into a self-exothermic reaction by the heat is stopped here for the time being, and then materials or material series (b) which cause a chemical change or a physical change by the reaction heat generated as a result of the self-exothermic reaction are described below.

Well-known chemical changes or physical changes caused by the reaction heat generated as a result of a self-exothermic reaction can be widely utilized, but preferably changes are from a hydrophobic change to a hydrophilic change. Any well-known materials or material series which perform such a change can be used in the present invention.

Another characteristic of the radian ray-sensitive lithographic printing plate precursor of the present invention is that the image-recording layer containing the above-described self-exothermic reactant contains, as the binder component, a resin having a siloxane bond (—Si—O—Si—) and a silanol group (—Si—OH) (hereinafter referred to as merely “a siloxane series resin”).

The surface of the image-recording layer of the lithographic printing plate precursor of the present invention becomes hydrophilic by the silanol group (—Si—OH).

The heat energy generated by the above-described self-exothermic reaction works upon the siloxane series resin contained in the image-recording layer to bring about a chemical change or a physical change to separate an image part from a non-image part, together with the above-described self-exothermic reactant.

In this case, the following two can be thought as the actions of the above-described heat energy: first, causing a dehydration condensation reaction between two silanol groups (—Si—OH) to convert them chemically to a hydrophobic siloxane bond (—Si—O—Si—), secondly, causing interfacial peeling of the image-recording layer from the support, or a physical change such as burning off of the image-recording layer followed by the abrasion of the surface of the support.

When the above-described chemical change is brought about to the siloxane series resin, the surface of the support used may be hydrophilic or hydrophobic. However, when the change is a physical change such as interfacial peeling of the image-recording layer from the support, the surface of the support used should be hydrophobic, and when the change is a physical change such as burning off of the image-recording layer and the abrasion of the surface of the support, the support used should be hydrophobic throughout.

In addition, when the image-recording layer further contains anatase-type titanium oxide fine particles (hereinafter sometimes referred to as merely “titanium oxide particles”), if UV exposure is performed for several minutes, contaminating substances adsorbed onto the surface of the image-recording layer are decomposed by the photocatalytic action of the titanium oxide particles, thereby the hydrophilicity of the surface can be maintained. In this case, the self-exothermic reactant contained in the image-recording layer of the lithographic printing plate precursor of the present invention is not influenced by the UV exposure.

Further, when a non-image part is formed on the image-recording layer by the above-described chemical change of the siloxane series resin, the titanium oxide particles outcropped on the surface of the non-image part form concavities and convexities on the surface, and moisture is easy to be retained due to these concavities and convexities (i.e., roughness), as a result, the non-image part is maintained more hydrophilic.

The explanation regarding the material or the material series which absorbs radiant rays, converts the absorbed radiant rays to heat, and enters into a self-exothermic reaction by the feat is finished for the time being, and the resin having a siloxane bond and a silanol group (a siloxane series resin) contained in the image-recording layer together with the self-exothermic reactant will be explained below.

The siloxane series resin contained in the image-recording layer of the lithographic printing plate precursor of the present invention is not particularly limited so long as it has a siloxane bond and a silanol group and can impart appropriate film strength and surface hydrophilicity as the image-recording layer, and examples of the siloxane series resins include those represented by the following formula (I):

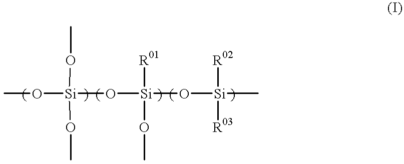

wherein at least any of R⁰¹, R⁰² and R⁰³ represents a hydroxyl group, and others may represent an organic residue selected from the groups represented by R⁰ in the following formula (II). The siloxane series resin represented by formula (I) is formed from the dispersion solution containing at least one of silane compounds represented by the following formula (II) by a sol-gel method.

(R⁰)ₙSi (Y)₄₋ₙ (II)

wherein at least one of R⁰ represents a hydroxyl group and others represent a hydrocarbon group or a heterocyclic group; Y represents a hydrogen atom, a halogen atom, or a group of formula —OR¹, —OCOR² or —N(R³) (R⁴) (wherein R¹ and R² each represents a hydrocarbon group, R³ and R⁴, which may be the same or different, each represents a hydrogen atom or a hydrocarbon group); and n represents 1, 2 or 3.

In formula (II), R⁰ preferably represents ahydroxyl group. Examples of the groups represented by R⁰ other than a hydroxyl group include a substituted or unsubstituted straight chain or branchedalkyl group having from 1 to 12 carbon atoms [e.g., methyl, ethyl, propyl, butyl, pentyl, hexyl, heptyl, octyl, nonyl, decyl, dodecyl, each of which may be substituted with one or more substituents such as a halogen atom (chlorine, fluorine, bromine), a hydroxyl group, a thiol group, a carboxyl group, a sulfo group, acyano group, an epoxy group, an—OR′ group (wherein R′ represents methyl, ethyl, propyl, butyl, heptyl, hexyl, octyl, decyl, propenyl, butenyl, hexenyl, octenyl, 2-hydroxyethyl, 3-chloropropyl, 2-cyanoethyl, N,N-dimethylaminoethyl, 2-bromo-ethyl, 2-(2-methoxyethyl)oxyethyl, 2-methoxycarbonylethyl, 3-carboxypropyl, benzyl), an —OCOR″ group (wherein R″ has the same meaning as R′), a —COOR″ group, a —COR″ group, an —N(R″′) (R″′) (wherein R″′ represents a hydrogen atom or the same group as R′, which may be the same or different), an —NHCONHR″ group, an —NHCOOR″ group, an —Si (R″)₃ group, a —CONHR″′ group, or an —NHCOR″ group]; a substituted or unsubstituted straight chain or branched alkenyl group having from 2 to 12 carbon atoms (e.g., vinyl, propenyl, butenyl, pentenyl, hexenyl, octenyl, decenyl, dodecenyl, each of which may be substituted with the same substituent as described above for the alkyl group); a substituted or unsubstituted aralkyl group having from 7 to 14 carbon atoms (e.g., benzyl, phenethyl, 3-phenylpropyl, naphthylmethyl, 2-naphthylethyl, each of which may be substituted with one or more substituents which is(are) the same substituent(s) as described above for the alkyl group); a substituted or unsubstituted alicyclic group having from5 to 10 carbon atoms (e.g., cyclopentyl, cyclohexyl, 2-cyclohexylethyl, 2-cyclopentylethyl, norbornyl, adamantyl, each of which may be substituted with one or more substituents which is(are) the same substituent(s) as described above for the alkyl group); a substituted or unsubstituted aryl group having from 6 to 12 carbon atoms (e.g., phenyl, naphthyl, each of which may be substituted with one or more substituents which is (are) the same substituent (s) as described above for the alkyl group); and a heterocyclic group, which may be ring-condensed, containing at least one atom selected from a nitrogen atom, an oxygen atom, and a sulfur atom (examples of the hetero atoms include a pyran ring, a furan ring, a thiophene ring, a morpholine ring, a pyrrole ring, a thiazole ring, an oxazole ring, a pyridine ring, a piperidine ring, a pyrrolidone ring, a benzothiazole ring, a benzoxazole ring, a quinoline ring, and a tetrahydrofuran ring, each of which may be substituted with one or more substituents which is(are) the same substituent(s) as described above for the alkyl group).

In formula (II), Y preferably represents a halogen atom (fluorine, chlorine, bromine, iodine), an —OR¹ group, an —OCOR² group, or an —N(R³)(R⁴) group.

In the —OR¹ group, R¹ represents a substituted or unsubstituted aliphatic group having from 1 to 10 carbon atoms (e.g., methyl, ethyl, propyl, butoxy, heptyl, hexyl, pentyl, octyl, nonyl, decyl, propenyl, butenyl, heptenyl, hexenyl, octenyl, decenyl, 2-hydroxyethyl, 2-hydroxypropyl, 2-methoxyethyl, 2-(methoxyethyloxo)ethyl, 2-(N,N-diethyl-amino) ethyl, 2-methoxypropyl, 2-cyanoethyl, 3-methyloxapropyl, 2-chloroethyl, cyclohexyl, cyclopentyl, cyclooctyl, chlorocyclohexyl, methoxycyclohexyl, benzyl, phenethyl, dimethoxybenzyl, methylbenzyl, bromobenzyl).

In the —OCOR² group, R² represents the same aliphatic group as in R¹, or a substituted or unsubstituted aromatic group having from 6 to 12 carbon atoms (e.g., the same aryl groups as described above for R⁰).

In the —N(R³) (R⁴) group, R³ and R⁴, which may be the same or different, each represents a hydrogen atom, or a substituted or unsubstituted aliphatic group having from 1 to 10 carbon atoms (e.g., the same groups as described above for R′ in the —OR′ group).

More preferably the total carbon atoms contained in R¹ and R² are 16 or less.

Specific examples of the silane compounds represented by formula (II) are shown below, but it should not be construed as the present invention is limited thereto: methyltrichlorosilane, methyltribromosilane, methyltrimethoxysilane, methyltriethoxysilane, methyltriisopropoxysilane, methyltri(t-butoxy)silane, ethyltrichlorosilane, ethyltribromosilane, ethyltrimethoxysilane, ethyltriethoxysilane, ethyltriisopropoxysilane, ethyltri(t-butoxy)silane, n-propyltrichlorosilane, n-propyltribromosilane, n-propyltrimethoxysilane, n-propyltriethoxysilane, n-propyltriisopropoxysilane, n-propyltri(t-butoxy)silane, n-hexyltrichlorosilane, n-hexyltribromosilane, n-hexyltrimethoxysilane, n-hexyltriethoxysilane, n-hexyltriisopropoxysilane, n-hexyltri(t-butoxy)silane, n-decyltrichlorosilane, n-decyltribromosilane, n-decyltrimethoxysilane, n-decyltriethoxysilane, n-decyltriisopropoxysilane, n-decyltri(t-butoxy) silane, n-octadecyltrichlorosilane, n-octadecyltribromosilane, n-octadecyltrimethoxysilane, n-octadecyltriethoxysilane, n-octadecyltriisopropoxysilane, n-octadecyltri(t-butoxy)silane, phenyltrichlorosilane, phenyltribromosilane, phenyltrimethoxysilane, phenyltriethoxysilane, phenyltriisopropoxysilane, phenyltri (t-butoxy) silane, tetrachlorosilane, tetrabromosilane, tetramethoxysilane, tetraethoxysilane, tetraisopropoxysilane, tetrabutoxysilane, dimethoxydiethoxysilane, dimethyldichlorosilane, dimethyldibromosilane, dimethyldimethoxysilane, dimethyldiethoxysilane, diphenyldichlorosilane, diphenyldibromosilane, diphenyldimethoxysilane, diphenyldiethoxysilane, phenylmethyldichlorosilane, phenylmethyldibromosilane, phenylmethyldimethoxysilane, phenylmethyldiethoxysilane, triethoxyhydrosilane, tribromohydrosilane, trimethoxyhydrosilane, triisopropoxyhydrosilane, tri(t-butoxy)hydrosilane, vinyltrichlorosilane, vinyltribromosilane, vinyltrimethoxysilane, vinyltriethoxysilane, vinyltriisopropoxysilane, vinyltri(t-butoxy)silane, trifluoropropyltrichlorosilane, trifluoropropyltribromosilane, trifluoropropyltrimethoxysilane, trifluoropropyltriethoxysilane, trifluoropropyltriisopropoxysilane, trifluoropropyltri(t-butoxy)silane, γ-glycidoxypropylmethyldimethoxysilane, γ-glycidoxypropylmethyldiethoxysilane, γ-glycidoxypropyltrimethoxysilane, γ-glycidoxypropyltriethoxysilane, γ-glycidoxypropyltriisopropoxysilane, γ-glycidoxypropyltri(t-butoxy)silane, γ-methacryloxypropylmethyldimethoxysilane, γ-methacryloxy-propylmethyldiethoxysilane, γ-methacryloxypropylmethoxysilane, γ-methacryloxypropyltriisopropoxysilane, γ-methacryloxypropyltri(t-butoxy)silane, γ-aminopropylmethyldimethoxysilane, γ-aminopropylmethyldiet,hoxysilane, γ-aminopropyltrimethoxysilane, γ-aminopropyltriethoxysilane, γ-aminopropyltriisopropoxysilane, γ-aminopropyltri(t-butoxy)-silane, γ-mercaptopropylmethyldimethoxysilane, γ-mercaptopropylmethyldiethoxysilane, γ-mercaptopropyltrimethoxysilane, γ-mercaptopropyltriethoxysilane, γ-mercaptopropyltriisopropoxysilane, γ-mercaptopropyltri(t-butoxy) silane, β-(3,4-epoxycyclohexyl)ethyltrimethoxysilane, and β-(3,4-epoxycyclohexyl)ethyltriethoxysilane.

In combination with the silane compound represented by formula (II) for use in the formation of the image-recording layer of the present invention, metal compounds capable of film-forming by a sol-gel method, such as Ti, Zn, Sn, Zr and Al compounds, can be used.

Examples of metal compounds usable in combination include Ti(OR″)₄ (wherein R″ represents methyl, ethyl, propyl, butyl, pentyl, hexyl), TiCl₄, Zn(OR″)₂, Zn(CH₃COCHCOCH₃)₂, Sn(OR″)₄, Sn(CH₃COCHCOCH₃)₄, Sn(OCOR″)₄, SnCl₄, Zr(OR″)₄, Zr(CH₃COCHCOCH₃)₄, and Al(OR″)₃.

Such metal compounds can be used in a proportion of not higher than 20 mol %, preferably not higher than 10 mol %, based on the silane compound used together. When formed by a sol-gel method within this range, sufficient uniformity and strength of the film can be obtained.

The image-recording layer of the lithographic printing plate precursor of the present invention may further contain anatase-type titanium oxide fine particles in addition to the self-exothermic reactant and the siloxane series resin.

If UV exposure is performed for several minutes, contaminating substances adsorbed onto the surface of the image-recording layer are decomposed by the photocatalytic action of the anatase-type titanium oxide particles contained in the image-recording layer, thereby the hydrophilicity of the surface can be maintained. In this case, the self-exothermic reactant contained in the image-recording layer of the lithographic printing plate precursor of the present invention is not influenced by the UV exposure.

Further, when a non-image part is formed on the image-recording layer by the above-described chemical change of the siloxane series resin, the anatase-type titanium oxide particles outcropped on the surface of the non-image part form concavities and convexities (i.e., roughness) on the surface, and moisture is easy to be retained due to these concavities and convexities (i.e., roughness), as a result, the non-image part is maintained more hydrophilic.

The anatase-type titaniumoxi define particles which may be contained in the image-recording layer of the lithographic printing plate precursor of the present invention are not particularly restricted so long as they are photo-excited by UV irradiation, the particle surface is hydrophilized to 20° or less in contact angle with water, and have an average particle diameter of from 5 to 500 nm, preferably from 5 to 100 nm.

If the average particle diameter is within the above range, the surface hydrophilization by UV irradiation can be effected appropriately and also it is advantageous to form concavities and convexities on the surface of the image-recording layer for easy retention of moisture.

Further, the phenomenon of conversion of the surface into hydrophilicity by light irradiation is described in detail in, for example, Toshiya Watanabe, Ceramics, 31 (No. 10), 837 (1966).

It is sufficient that at least 30 wt % (preferably 50 wt % or more) of the crystals of anatase-type titanium oxide particles have anatase-type crystal structure.

Anatase-type titanium oxide particles are commercially available as powders or titania sol dispersion solutions, e.g., from Ishihara Sangyo Kaisha Ltd., Titan Kogyo Co., Ltd., Sakai Chemical Industry Co., Ltd., Nippon Aerosil Co., Ltd., Nissan Chemical Industries, Ltd., etc.

Further, anatase-type titanium oxide particles which can be used in the present invention may contain other metal elements or their oxides. The terminology “contain” means coating, carrying or doping them on the surface and/or in the interior of particles.

Examples of metal elements which may be contained include Si, Mg, V, Mn, Fe, Sn, Ni, Mo, Ru, Rh, Re, Os, Cr, Sb, In, Ir, Ta, Nb, Cs, Pd, Pt, Au, etc., specifically they are disclosed in JP-A-7-228738, JP-A-7-187677, JP-A-8-81223, JP-A-8-257399, JP-A-8-283022, JP-A-9-25123, JP-A-9-71437, JP-A-9-70532, etc.

In the image-recording layer of the lithographic printing plate precursor of the present invention, the ratio of the anatase-type titanium oxide fine particles to the siloxane series resin is preferably from 45/55 to 90/10 by weight, more preferably from 60/40 to 80/20 by weight.

In this range, the film strength of the image-recording layer and the hydrophilicity of the surface after UV irradiation can be retained satisfactorily, thereby a great number of background stain-free clear printed matters can be produced.

The image-recording layer of the lithographic printing plate precursor of the present invention may further contain inorganic pigment particles other than anatase-type titanium oxide particles, e.g., silica, alumina, kaolin, clay, zinc oxide, calcium carbonate, barium carbonate, calcium sulfate, barium sulfate, magnesium carbonate, titanium oxide other than anatase-type crystals. These inorganic pigments are used in a proportion of not more than 40 parts by weight, preferably not more than 30 parts by weight, based on the anatase-type titanium oxide particles of the present invention.

The image-recording layer of the lithographic printing plate precursor of the present invention is preferably formed by a sol-gel method, and conventionally well-known sol-gel methods can be used in the present invention.

Specifically, the image-recording layer of the present invention can be formed according to the method described in detail in the literature, e.g., Sumio Sakibana, Science of Sol-Gel Method, Agne Showfu-sha (1988), and Seki Hirashima, The Latest Arts of Functional Thin Film Formation Using Sol-Gel Method, Sogo Gijutsu Center (1992).

In a coating solution for the image-recording layer, water is used as a solvent, and further incorporated with a water-soluble solvent in order to prevent the precipitation upon preparation of the coating solution for effecting homogeneous liquefaction. Examples of water-soluble solvents include alcohols (e.g., methanol, ethanol, propyl alcohol, ethylene glycol, diethylene glycol, propylene glycol, dipropylene glycol, ethylene glycol monomethyl ether, propylene glycol monomethyl ether, ethylene glycol monoethyl ether), ethers (e.g., tetrahydrofuran, ethylene glycol dimethyl ether, propylene glycol dimethyl ether, tetrahydrofuran), ketones (e.g., acetone, methyl ethyl ketone, acetylacetone), esters (e.g., methyl acetate, ethylene glycol monomethylmonoacetate), and amides (e.g., formamide, N-methylformamide, pyrrolidone, N-methylpyrrolidone), and these solvents may be used alone or two or more may be used as a mixture.

Further, it is preferred to use acidic or basic catalyst in the coating solution for the purpose of accelerating the hydrolysis and polycondensation reaction of the silane compound represented by formula (II) and the above-described metal compound used in combination therewith.

The catalyst used for the above purpose is an acidic or basic compound as it is or dissolved in water or a solvent such as alcohol (such a compound is hereinafter referred to as an acidic catalyst or a basic catalyst, respectively). The concentration of the catalyst is not particularly restricted, but when the catalyst with high concentration is used, the hydrolysis rate and the polycondensation rate are liable to be increased. However, since the basic catalyst used in a high concentration sometimes causes precipitation in the sol solution, it is preferred that the basic catalyst concentration be not higher than 1 N (the concentration in the aqueous solution).

The kind of the acidic or basic catalyst used is not particularly limited, but when the use of the catalyst in a high concentration is required, the catalyst constituted of elements which leave no residue in catalyst crystals upon sintering is preferred. Specific examples of acidic catalysts include hydrogen halides (e.g., hydrochloric acid), nitric acid, sulfuric acid, sulfurous acid, hydrogen sulfide, perchloric acid, hydrogen peroxide, carbonic acid, carboxylic acids (e.g., formic acid and acetic acid), substituted carboxylic acids (e.g., R of the structural formula R—COOH is substituted with other elements or substituents), and sulfonic acids (e.g., benzenesulfonic acid) Specific examples of basic catalysts include ammoniacal bases (e.g., aqueous ammonia) and amines (e.g., ethylamine, aniline)

The thus-prepared coating solution is coated on a support using any of conventionally well-known coating methods, and dried to form an image-recording layer.

The film thickness of the image-recording layer thus-formed is preferably from 0.2 to 10 μm, more preferably from 0.5 to 8 μm. In this thickness range, the layer formed can have a uniform thickness and sufficient film strength.

Polymer compounds having a functional group which generates a sulfonic acid by heating are particularly preferred as a separating means of an image part from a non-image part. As such compounds, for example, in a variety of sulfonic acid-generating type light/acid generating agents for use as a photosensitive resin composition of a chemical amplification type, there are many polymer compounds having at main chain or side chain functional groups which generate sulfonic acid also by heating (hereinafter referred to as “a sulfonic acid-generating type polymer compound”) . When the functional group which generates a sulfonic acid by heating is at least one compound represented by formula (1), (2) or (3), such polymer compounds are particularly preferably used as the above-described material or material series having the function of item (b).

Polymer compounds having a functional group represented by formula (1), (2) or (3) according to the present invention are described in further detail below.

When R¹ to R⁵ each represents an (unsubstituted) aryl group or a substituted aryl group, examples of the aryl group includes a carbocyclic aryl group and a heterocyclic (hetero) aryl group. Examples of carbocyclic aryl groups include a phenyl group, a naphthyl group, an anthracenyl group, and a pyrenyl group each having from 6 to 19 carbon atoms. Examples of heterocyclic aryl groups include a pyridyl group, a furyl group, a quinolyl group condensed with a benzene ring, a benzofuryl group, a thioxanthone group, a carbazole group each having from 3 to 20 carbon atoms and from 1 to 5 hetero atoms. When R¹ to R⁵ each represents an (unsubstituted) alkyl group or a substituted alkyl group, examples of the alkyl group include a straight chain, branched or cyclic alkyl group having from 1 to 25 carbon atoms (e.g., methyl, ethyl, isopropyl, t-butyl, cyclohexyl).

When R¹ to R⁵ each represents a substituted aryl group, a substituted heteroaryl group, or a substituted alkyl group, examples of substituents include an alkoxyl group having from 1 to 10 carbon atoms (e.g., methoxy, ethoxy); a halogen atom (e.g., fluorine, chlorine, bromine); a halogen-substituted alkyl group (e.g., trifluoromethyl, trichloromethyl); an alkoxycarbonyl or aryloxycarbonyl group having from 2 to 15 carbon atoms (e.g., methoxycarbonyl, ethoxycarbonyl, t-butyloxycarbonyl, p-chlorophenyloxycarbonyl); a hydroxyl group; an acyloxy group (e.g., acetyloxy, benzoyloxy, p-diphenylaminobenzoyloxy); a carbonate group (e.g., t-butyloxycarbonyloxy); an ether group (e.g., t-butyloxycarbonylmethyloxy, 2-pyranyloxy), a substituted or unsubstituted amino group (e.g., amino, dimethylamino, diphenylamino, morpholino, acetylamino); a thioether group (e.g., methylthio, phenylthio); an alkenyl group (e.g., vinyl, styryl); a nitro group; a cyano group; an acyl group (e.g., formyl, acetyl, benzoyl); an aryl group (e.g., phenyl, naphthyl); andaheteroaryl group (e.g., pyridyl). Further, when R¹ to R⁵ each represents a substituted aryl group or a substituted heteroaryl group, an alkyl group (e.g., methyl, ethyl) can be used as substituents in addition to the above-described substituents.

When R¹ represents a cyclic imido group, examples of cyclic imido groups for use in the present invention include cyclic imido groups having from 4 to 20 carbon atoms (e.g., succinimido, phthalimido, cyclohexanedicarboxylic acid imido, norbornenedicarboxylic acid imido).

In formula (1), R¹ preferably represents an aryl group substituted with an electron attractive group such as halogen, cyano, nitro, etc.; an alkyl group substituted with an electron attractive group such as halogen, cyano, nitro, etc.; a secondary or tertiary branched alkyl group; a cyclic alkyl group; or a cyclic imido group. A secondary alkyl group represented by formula (4) is more preferred in that sensitivity and the aging stability can be compatible.

R⁶ and R⁷ each represents a substituted or unsubstituted alkyl group, or a substituted or unsubstituted aryl group, and further, R⁶ and R⁷ may form a ring together with the secondary carbon atom (CH) to which they are bonded.

When R6 and R⁷ each represents a substituted or unsubstituted alkyl group, preferred examples of the alkyl group include a straight chain, branched or cyclic alkyl group having from 1 to 25 carbon atoms (e.g., methyl, ethyl, isopropyl, t-butyl, cyclohexyl).

When R⁶ and R⁷ each represents a substituted or unsubstituted aryl group, examples of the aryl group includes a carbocyclic aryl group and a heterocyclic aryl group. Examples of carbocyclic aryl groups include a phenyl group, a naphthyl group, an anthracenyl group, and a pyrenyl group each having from 6 to 19 carbon atoms. Examples of heterocyclic aryl groups include a pyridyl group, a furyl group, a quinolyl group condensed with a benzene ring, a benzofuryl group, a thioxanthone group, and a carbazole group each having from 3 to 20 carbon atoms and from 1 to 5 hetero atoms.

When R⁶ and R⁷ each represents a substituted alkyl group or a substituted aryl group, examples of substituents include an alkoxyl group having from 1 to 10 carbon atoms (e.g., methoxy, ethoxy); a halogen atom (e.g., fluorine, chlorine, bromine); a halogen-substituted alkyl group (e.g., trifluoromethyl, trichloromethyl); an alkoxycarbonyl or aryloxycarbonyl group having from 2 to 15 carbon atoms (e.g., methoxycarbonyl, ethoxycarbonyl, t-butyloxycarbonyl, p-chlorophenyloxycarbonyl); a hydroxyl group; an acyloxy group (e.g., acetyloxy, benzoyloxy, p-diphenylaminobenzoyloxy); a carbonate group (e.g., t-butyloxycarbonyloxy); an ether group (e.g., t-butyloxycarbonylmethyloxy, 2-pyranyloxy), a substituted or unsubstituted amino group (e.g., amino, dimethylamino, diphenylamino, morpholino, acetylamino); athioether group (e.g., methylthio, phenylthio); an alkenyl group (e.g., vinyl, styryl); a nitro group; a cyano group; an acyl group (e.g., formyl, acetyl, benzoyl); anaryl group (e.g., phenyl, naphthyl); and a heteroaryl group (e.g., pyridyl).

Further, when R⁶ and R⁷ each represents a substituted aryl group, an alkyl group (e.g., methyl, ethyl) can be used as substituents in addition to the above-described substituents.

R⁶ and R⁷ preferably represent a substituted or unsubstituted alkyl group in view of excellent storage stability, and particularly preferably represent a secondary alkyl group substituted with an electron attractive group such as an alkoxyl group, a carbonyl group, an alkoxycarbonyl group, a cyano group, a halogen atom, etc., or a secondary alkyl group such as a cyclohexyl group or a norbornyl group in view of excellent aging stability. From a physical property value, compounds whose chemical shift of a secondary methine hydrogen at proton NMR in heavy chloroform appears at low magnetic field of preferably less than 4.4 ppm, more preferably less than 4.6 ppm, on the basis of TMS, are preferred.

The reason that a secondary alkyl group substituted with an electron attractive group is particularly preferred is that a carbocation which is supposed to have been formed during pyrolytic reaction as an intermediate is made labile by the electron attractive group and decomposition at room temperature with the lapse of time is inhibited.

Specifically, structures represented by the following formulae are particularly preferred as the structure of —CHR⁶R⁷.

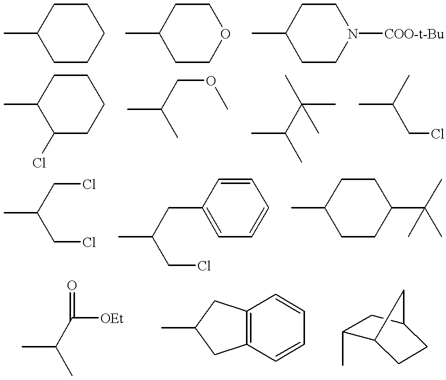

In formulae (2) and (3), R² to R⁵ each particularly preferably represents an aryl group substituted with an electron attractive group such as halogen, cyano, nitro, etc., an alkyl group substituted with an electron attractive group such as halogen, cyano, nitro, etc., or a secondary or tertiary branched alkyl group.

A polyvalent linking group comprising nonmetal atoms represented by L is a linking group comprising from 1 to 60 carbon atoms, from 0 to 10 nitrogen atoms, from 0 to 50 oxygen atoms, from 1 to 100 hydrogen atoms, and from 0 to 20 sulfur atoms. As specific examples of linking groups, those comprising the following structural unit in combination can be used.

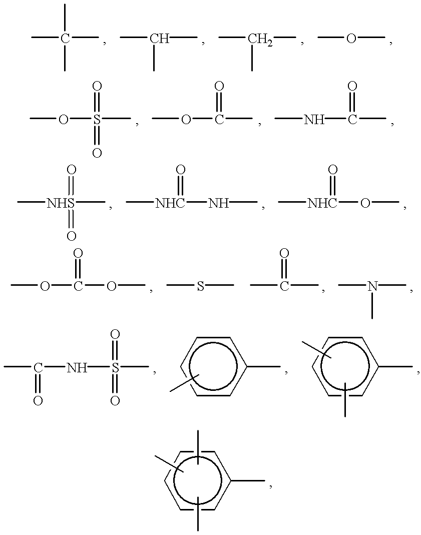

polyvalent naphthalene, polyvalent anthracene.

When the polyvalent linking group has a substituent, the following substituents can be used: an alkyl group having from 1 to 20 carbon atoms (e.g., methyl, ethyl), an aryl group having from 6 to 16 carbon atoms (e.g., phenyl, naphthyl), a hydroxyl group, a carboxyl group, a sulfonamido group, an N-sulfonylamido group, an acyloxy group having from 1 to 6 carbon atoms (e.g., acetoxy), an alkoxyl group having from 1 to 6 carbon atoms (e.g., methoxy, ethoxy), a halogen atom (e.g., chlorine, bromine), an alkoxycarbonyl group having from 2 to 7 carbon atoms (e.g., methoxycarbonyl, ethoxycarbonyl, cyclohexyloxycarbonyl), a cyano group, or a carbonate group (e.g., t-butylcarbonate).

Specific examples of monomers which are preferably used to synthesize polymer compounds having a functional group represented by formula (1), (2) or (3) at side chain are shown below.

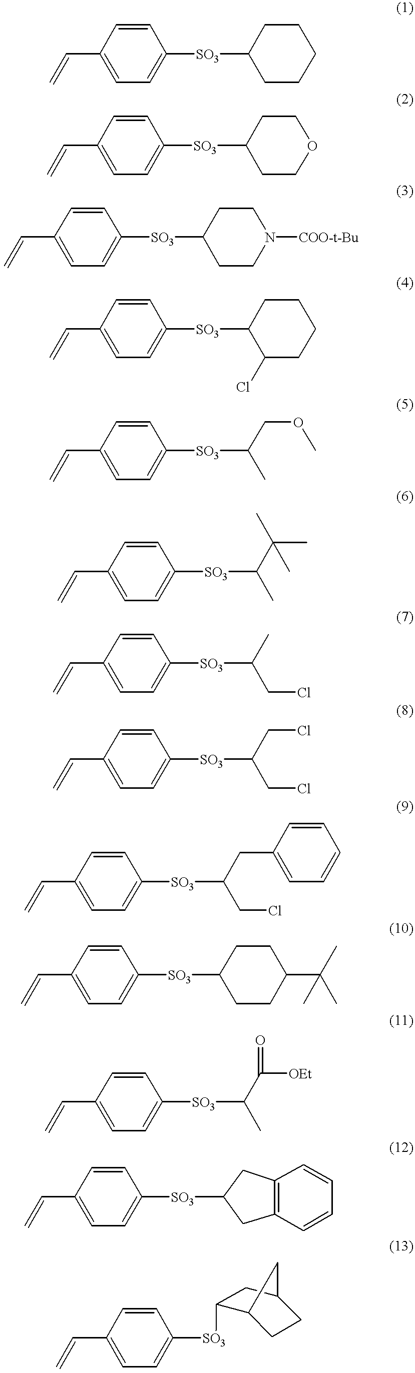

In the present invention, polymer compounds obtained by radical polymerizing at least any one monomer having a functional group represented by formula (1), (2) or (3) are preferably used. As such polymer compounds, homopolymers comprising only one kind of monomer having a functional group represented by formula (1), (2) or (3) may be used, but copolymers comprising two or more monomers or copolymers comprising these monomers with other monomers may be used.

In the present invention, more preferred polymer compounds are copolymers obtained by radical polymerization of the above-described monomers with other well-known monomers.

As other monomers, monomers having crosslinking reactivity such as glycidyl methacrylate, N-methylol methacrylamide, ω-(trimethoxysilyl)propyl methacrylate, 2-isocyanate ethyl acrylate are preferably used.

Well-known other monomers such as acrylates, methacrylates, acrylamides, methacrylamides, vinyl esters, styrenes, acrylic acid, methacrylic acid, acrylonitrile, maleic anhydride, and maleinimide can also be used in copolymers.

Specific examples of acrylates include methyl acrylate, ethyl acrylate, (n- or i-)propyl acrylate, (n-, i-, sec- or t-) butyl acrylate, amyl acrylate, 2-ethylhexyl acrylate, dodecyl acrylate, chloroethyl acrylate, 2-hydroxyethyl acrylate, 2-hydroxypropyl acrylate, 5-hydroxypentyl acrylate, cyclohexyl acrylate, allyl acrylate, trimethylolpropane monoacrylate, pentaerythritol monoacrylate, benzyl acrylate, methoxybenzyl acrylate, chlorobenzyl acrylate, hydroxybenzyl acrylate, hydroxyphenethyl acrylate, dihydroxyphenethyl acrylate, furfuryl acrylate, tetrahydrofurfuryl acrylate, phenyl acrylate, hydroxyphenyl acrylate, chlorophenyl acrylate, sulfamoylphenyl acrylate, and 2-(hydroxyphenylcarbonyloxy)ethyl acrylate.

Specific examples of methacrylates include methyl methacrylate, ethyl methacrylate, (n- or i-)propyl methacrylate, (n-, i-, sec- or t-)butyl methacrylate, amyl methacrylate, 2-ethylhexyl methacrylate, dodecyl methacrylate, chloroethyl methacrylate, 2-hydroxyethyl methacrylate, 2-hydroxypropyl methacrylate, 5-hydroxypentyl methacrylate, cyclohexyl methacrylate, allyl methacrylate, trimethylolpropane monomethacrylate, pentaerythritol monomethacrylate, glycidyl methacrylate, benzyl methacrylate, methoxybenzyl methacrylate, chlorobenzyl methacrylate, hydroxybenzyl methacrylate, hydroxyphenethyl methacrylate, dihydroxyphenethyl methacrylate, furfuryl methacrylate, tetrahydrofurfuryl methacrylate, phenyl methacrylate, hydroxyphenyl methacrylate, chlorophenyl methacrylate, sulfamoylphenyl methacrylate, and 2-(hydroxyphenylcarbonyloxy)ethyl methacrylate.

Specific examples of acrylamides include acrylamide, N-methylacrylamide, N-ethylacrylamide, N-propylacrylamide, N-butylacrylamide, N-benzylacrylamide, N-hydroxyethylacrylamide, N-phenylacrylamide, N-tolylacrylamide, N-(hydroxyphenyl)acrylamide, N-(sulfamoylphenyl)acrylamide, N-(phenylsulfonyl)acrylamide, N-(tolylsulfonyl)acrylamide, N,N-dimethylacrylamide, N-methyl-N-phenylacrylamide, and N-hydroxyethyl-N-methylacrylamide.

Specific examples of methacrylamides include methacrylamide, N-methylmethacrylamide, N-ethylmethacrylamide, N-propylmethacrylamide, N-butylmethacrylamide, N-benzylmethacrylamide, N-hydroxyethylmethacrylamide, N-phenylmethacrylamide, N-tolylmethacrylamide, N-(hydroxyphenyl)methacrylamide, N-(sulfamoylphenyl)methacrylamide, N-(phenylsulfonyl)methacrylamide, N-(tolylsulfonyl)methacrylamide, N,N-dimethylmethacrylamide, N-methyl-N-phenylmethacrylamide, and N-hydroxyethyl-N-methylmethacrylamide.

Specific examples of vinyl esters include vinyl acetate, vinyl butyrate, and vinyl benzoate.

Specific examples of styrenes include styrene, methylstyrene, dimethylstyrene, trimethylstyrene, ethylstyrene, propylstyrene, cyclohexylstyrene, chloromethylstyrene, trifluoromethylstyrene, ethoxymethylstyrene, acetoxymethylstyrene, methoxystyrene, dimethoxystyrene, chlorostyrene, dichlorostyrene, bromostyrene, iodostyrene, fluorostyrene, and carboxystyrene.

Among these other monomers, particularly preferably used are acrylates, methacrylates, acrylamides, methacrylamides, vinyl esters, styrenes, acrylic acid, methacrylic acid, and acrylonitrile, each having 20 or less carbon atoms.

The proportion of monomers having a functional group represented by formula (1), (2) or (3) which are used in the synthesis of copolymers is preferably from 5 to 99% by weight, more preferably from 10 to 95% by weight.

Specific examples of polymer compounds having a functional group represented by formula (1), (2) or (3) at side chain are shown below.

Numerals in a formula indicates mol composition of the polymer compound.

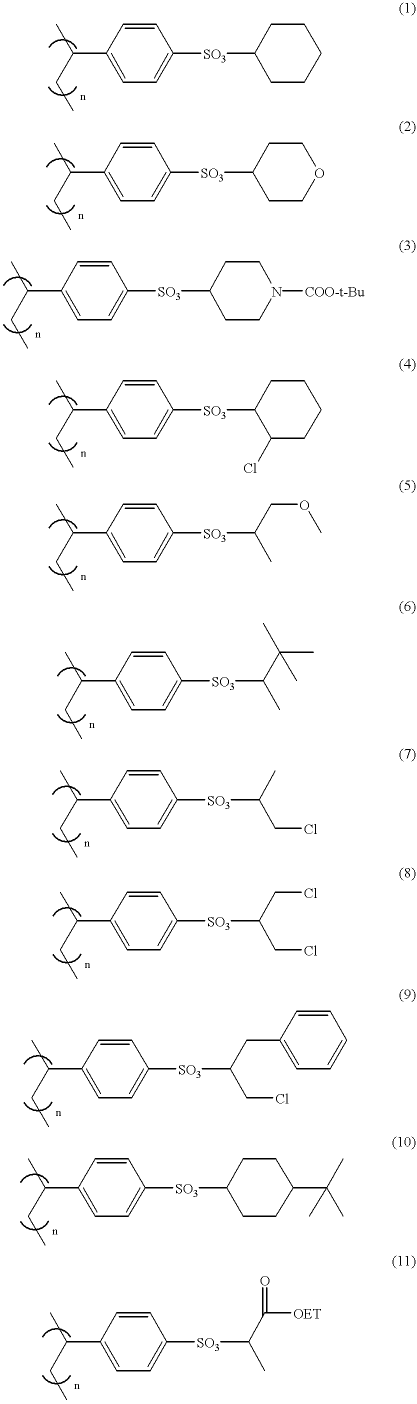

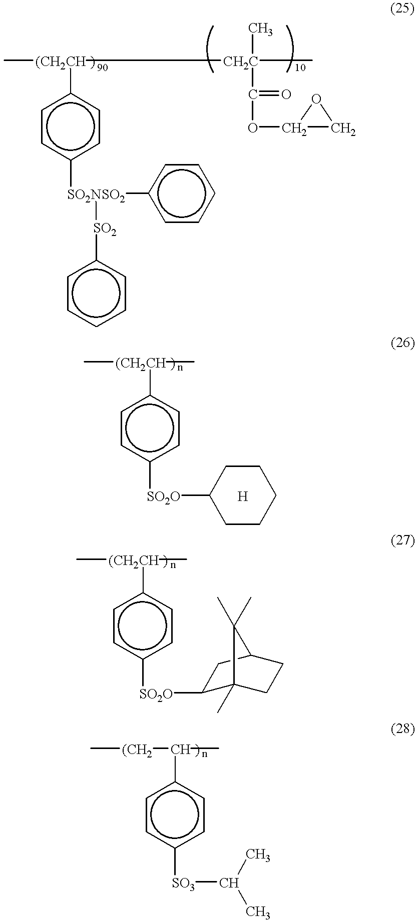

The weight average molecular weight of the polymer compound having at least any one functional group represented by formula (1), (2) or (3) for use in the present invention is preferably 2,000 or more, more preferably from 5,000 to 300,000, and the number average molecular weight is preferably 800 or more, more preferably from ,1000to250,000. The poly dispersion degree (weight average molecular weight/number average molecular weight) is preferably 1 or more, more preferably from 1.1 to 10.

These polymer compounds may be any of a random polymer, a block polymer, or a graft polymer, but preferably a random polymer.

In the synthesis of a sulfonic acid-generating type polymer compound for use in the present invention, the following solvents can be used alone or in combination of two or more, e.g., tetrahydrofuran, ethylene dichloride, cyclohexanone, methyl ethyl ketone, acetone, methanol, ethanol, ethylene glycol monomethyl ether, ethylene glycol monoethyl ether, 2-methoxyethyl acetate, diethylene glycol dimethyl ether, 1-methoxy-2-propanol, 1-methoxy-2-propyl acetate, N,N-dimethylformamide, N,N-dimethylacetamide, ethyl acetate, methyl lactate, ethyl lactate, dimethylsulfoxide, and water.

As radical polymerization initiators for use in the synthesis of a sulfonic acid-generating type polymer compound according to the present invention, well-known compounds such as azo-based initiators and peroxide initiators can be used.

A sulfonic acid-generating type polymer compound according to the present invention can be used in combination with the acid generators disclosed in JP-A-10-207068 and the base generators disclosed in JP-A-10-221842.

By way of an example, a copolymer comprising a monomer which generates a sulfonic acid group and a monomer having a group capable of reacting with a crosslinking agent can be reacted with a crosslinking agent to harden the polymer.

Light/Heat Conversion Material

In a heat-sensitive lithographic printing plate precursor according to the present invention, in a material or material series (a) which is “a materials or a material series which starts a self-exothermic reaction using the heat obtained as a result of light/heat conversion”, there are a case in which a light/heat conversion material per se is a self-exothermic reaction component, and a case in which a light/heat conversion material per se does not enter into a self-exothermic reaction but a material series (a) contains a component which causes a self-exothermic reaction. Here, a light/heat conversion material in the latter case is described. As light/heat conversion materials which are used for this purpose, any material which can absorb light, e.g., ultraviolet ray, visible ray, infrared ray, white light, etc., and convert the absorbed light to heat can be used, for example, a carbon black, a carbon graphite, a pigment, a phthalocyanine-based pigment, an iron powder, a graphite powder, an iron oxide powder, a leadoxide, a silver oxide, a chromium oxide, an iron sulfide, and a chromium sulfide can be exemplified as such examples. Particularly preferred are dyes, pigments or metals which effectively absorb infrared ray of the wavelength of from 760 to 1,200 nm. These light/heat conversion materials are of course further combined with a self-exothermic reactant.

Well-known commercially available dyes and dyes described in literature (e.g., Senryo Binran (Dye Handbook), compiled by Yuki Gosei Kagaku Kyokai, 1970) can be used as a light/heat conversion material in a material series (a). Specifically, an azo dye, a metal complex salt azo dye, a pyrazolone azo dye, an anthraquinone dye, a phthalocyanine dye, a carbonium dye, a quinonimine dye, a methine dye, a cyanine dye, a metal thiolate complex can be exemplified as such dyes.

Examples of preferred dyes include cyanine dyes disclosed in JP-A-58-125246, JP-A-59-84356, JP-A-59-202829, and JP-A-60-78787; methine dyes disclosed in JP-A-58-173696, JP-A-58-181690, and JP-A-58-194595; naphthoquinone dyes disclosed in JP-A-58-112793, JP-A-58-224793, JP-A-59-48187, JP-A-59-73996, JP-A-60-52940, JP-A-60-63744; squarylium dyes disclosed in JP-A-58-112792; cyanine dyes disclosed in British Patent 434,875; near infrared absorbing sensitizers disclosed in U.S. Pat. No. 5,156,938; a substituted arylbenzo(thio)pyrylium salt disclosed in U.S. Pat. No. 3,881,924; and a trimethine thiapyrylium salt disclosed in JP-A-57-142645 (corresponding to U.S. Pat. No. 4,327,169).

Of these dyes, particularly preferred dyes are a cyanine dye, a squarylium dye, a pyrylium salt and a nickel thiolate complex.

In the present invention, a pigment can be used for the same purpose as the above dyes, i.e., as a component having a light/heat converting function in material series (a). Pigments preferred for this purpose are commercially available pigments, and pigments described in Color Index (C.I.) Handbook, Saishin Ganryo Binran (The Latest Pigment Handbook), compiled by Nihon Ganryo Gijutsu Kyokai, 1977, Saishin Ganryo Oyo Gijutsu (Application Techniques of the Latest Pigment), CMC Publishing Co., 1986, and Insatsu Ink Gijutsu (Techniques of Printing Ink), CMC Publishing Co., 1984.

The particle size of pigments is preferably from 0.01 to 10 μm, more preferably from 0.05 to 1 μm, and particularly preferably from 0.1 to 1 μm. When the particle size of pigments is less than 0.01 μm, the stability of a dispersion product in a photosensitive layer-coating solution is inferior, while when it exceeds 10 μm, an image-recording layer becomes uneven.

Well-known dispersing methods used in the production of inks and toners can be used for dispersing pigments. A dispersing machine such as an ultrasonic disperser, a sand mill, an attriter, a pearl mill, a super mill, a ball mill, an impeller, a disperser, a KD mill, a colloid mill, Dynatron, a three-roll mill, and a pressure kneader can be used for dispersion. Details of these are described in Saishin Ganryo Oyo Gilutsu, CMC Publishing Co., 1986.

Other Components

In the present invention, the above-described two elements are requisite as materials or material series (a) and (b), but various other compounds may be added other than these compounds, if necessary. For example, a dye having a high absorbing property in a visible ray region can be used as a coloring agent of an image.

Specific examples of the dye as a coloring agent include, Oil Yellow #101, Oil Yellow #103, Oil Pink #312, Oil Green BG, Oil Blue BOS, Oil Blue #603, Oil Black BY, Oil Black BS, Oil Black T-505 (products of Orient Chemical Industry Co., Ltd.), Victoria Pure Blue, CrystalViolet (C.I. 42555), MethylViolet (C.I. 42535), Ethyl Violet, Rhodamine B (C.I. 145170B), Malachite Green (C.I. 42000), Methylene Blue (C.I. 52015), and dyes disclosed in JP-A-62-293247.

These dyes are preferably added as they are discolored after laser exposure and the image part and the non-image part are distinguished. The addition amount of these dyes is from 0.01 to 10% by weight based on the entire solid contents of the printing plate precursor materials.

For broadening the stability for printing conditions, nonionic surfactants as disclosed in JP-A-62-251740 and JP-A-3-208514, and amphoteric surfactants as disclosed in JP-A-59-121044 and JP-A-4-13149 can be added to a recording layer according to the present invention.

Specific examples of nonionic surfactants include sorbitan tristearate, sorbitan monopalmitate, sorbitan trioleate, stearic acid monoglyceride, and polyoxyethylenenonylphenyl ether.

Specific examples of amphoteric surfactants include alkyldi(aminoethyl)glycine, alkylpolyaminoethylglycine hydrochloride, 2-alkyl-N-carboxyethyl-N-hydroxyethylimidazolinium betaine and an N-tetradecyl-N,N-betaine type amphoteric surfactant (e.g., Amorgen K, trade name, a product of Daiichi Industry Co., Ltd.).

The proportion of these nonionic surfactants and amphoteric surfactants in the image-recording material is preferably from 0.05 to 15% by weight, more preferably from 0.1 to 5% by weight.

A plasticizer is added to a recording layer according to the present invention for imparting flexibility to a coating film, if necessary, e.g., polyethylene glycol, tributyl citrate, diethyl phthalate, dibutyl phthalate, dihexyl phthalate, dioctyl phthalate, tricresyl phosphate, tributyl phosphate, trioctyl phosphate, tetrahydrofurfuryl oleate, oligomers and polymers of acrylic acid or methacrylic acid.

Besides these compounds, epoxy compounds, vinyl ethers, phenol compounds having a hydroxymethyl group and phenol compounds having an alkoxymethyl group as disclosed in JP-A-8-276558 may be added. Further, other polymer compounds may be added for improving the coating film strength.

A lithographic printing plate precursor according to the present invention can be produced generally by dissolving the above-described each component in a solvent and coating the resulting coating solution on an appropriate support. Examples of the solvents for use herein include ethylene dichloride, cyclohexanone, methyl ethyl ketone, methanol, ethanol, propanol, ethylene glycol monomethyl ether, 1-methoxy-2-propanol, 2-methoxyethyl acetate, 1-methoxy-2-propyl acetate, dimethoxyethane, methyl lactate, ethyl lactate, N,N-dimethylacetamide, N,N-dimethylformamide, tetramethylurea, N-methylpyrrolidone, dimethyl sulfoxide, sulfolane, γ-butyrolactone, toluene, water, etc., but solvents are not limited thereto.

These solvents are used alone or as a mixture. The concentration of the above components (all solid contents including additives) in a solution is preferably from 1 to 50% by weight. The dry coating weight of solid contents on a support varies according purposes, but in the case of a lithographic printing plate precursor, it is generally preferably from 0.5 to 5.0 g/m². Various coating methods can be used in the present invention, e.g., bar coater coating, rotary coating, spray coating, curtain coating, dip coating, air knife coating, blade coating and roll coating.

For improving coating property, a surfactant, e.g., fluorine-based surfactants as disclosed in JP-A-62-170950, can be added to a recording layer in the present invention. The coating amount of a surfactant is preferably from 0.01 to 1% by weight, more preferably from 0.05 to 0.5% by weight, based on the entire solid contents of the image-recording material.

A support for use in the present invention is preferably a plate-like support having dimensional stability. For example, paper, paper laminated with plastics (e.g., polyethylene, polypropylene, polystyrene), a metal plate (e.g., aluminum, zinc, copper), a plastic film (e.g., cellulose diacetate, cellulose triacetate, cellulose propionate, cellulose butyrate, cellulose acetate butyrate, cellulose nitrate, polyethylene terephthalate, polyethylene, polystyrene, polypropylene, polycarbonate, polyvinyl acetal), and paper or a plastic film laminated or deposited with the above metals can be exemplified.

A polyester film or an aluminum plate is preferably used as a support in the present invention and an aluminum plate is particularly preferred of these as aluminum is dimensionally stable and comparatively inexpensive. A preferred aluminum plate is a pure aluminum plate or an alloy plate containing aluminum as a main component and a trace amount of different elements, and a plastic film laminated or deposited with aluminum may also be used. Examples of different elements contained in the aluminum alloy include silicon, iron, manganese, copper, magnesium, chromium, zinc, bismuth, nickel, titanium, etc. The content of different elements in the aluminum alloy is at most 10% by weight or less. In the present invention, particularly preferred aluminum is pure aluminum but 100% pure aluminum is difficult to produce from the refining technique, accordingly, an extremely small amount of different elements may be contained. The composition of an aluminum plate used in the present invention is not specified as described above, and conventionally well-known and commonly used aluminum materials can be used arbitrarily. An aluminum plate for use in the present invention has a thickness of from about 0.1 to about 0.6 mm, preferably from 0.15 to 0.4 mm, and particularly preferably from 0.2 to 0.3 mm.

Prior to surface graining of an aluminum plate, if desired, degreasing treatment for removing the rolling oil on the surface of the plate is conducted using a surfactant, an organic solvent or an alkaline aqueous solution, for example.

Surface graining treatment of an aluminum plate can be carried out by various methods, e.g., mechanical graining, electrochemical graining by dissolving the surface, and chemical graining by selectively dissolving the surface. As mechanical graining, well-known methods, e.g., a ball rubbing method, a brush abrading method, a blasting method, or a buffing method, can be used. As electrochemical graining, a method of graining the surface in a hydrochloric acid or nitric acid-electrolytic solution by alternating current or direct current. Further, both methods can be used in combination as disclosed in JP-A-54-63902.

Further, as stated above, when the chemical change that the image-recording layer of the lithographic printing plate precursor of the present invention changes from hydrophilic to hydrophobic is brought about, the surface of the support may be hydrophilic or hydrophobic.

However, when the change brought about is a physical change such as interfacial peeling of the image-recording layer from the support, the surface of the support should be hydrophobic, and when the change is a physical change such as the abrasion of the surface of the support, the support used should be hydrophobic throughout.

Thus, a lithographic printing plate precursor according to the present invention can be produced. The thus-obtained lithographic printing plate precursor is imagewise exposed by a solid laser or a semiconductor laser which radiates infrared rays of wavelength of from 760 to 1,200 nm. In the present invention, dissolution treatment is not necessary and a printing plate can be set on a printing machine immediately after laser irradiation, but it is preferred to conduct heating treatment between the laser irradiation process and the printing process. Heating treatment condition is preferably from 80 to 150° C. for 10 seconds to 5 minutes. By this heating treatment, the laser energy necessary for recording can be reduced at laser irradiation.

Further, recording of image information on a lithographic printing plate precursor is not limited to the above-described imagewise irradiation of radiant rays and image recording by imagewise heat transfer by a thermal head of a heat transfer printer etc. is also preferred.

The thus-obtained lithographic printing plate is set on an offset printing machine etc. and used for printing a multiple number of sheets.

The present invention will be described in detail with referring to examples but it should not be construed as the present invention is limited thereto.

### EXAMPLES I-1 TO I-8

Lithographic printing plate precursors comprising an iron powder as a material (a) having a light/heat conversion function and a self-exothermic reaction function, and a polymer compound generating a sulfonic acid by heating as a material (b) having a separating function of an image part from a non-image part were prepared.

Iron Fine Powder

The above-described alloy of iron fine powder having Fe/Co/Al/Y ratio of 100/20/5/5, a particle size having a long axis length of 0.1 μm, a short axis length of 0.02 μm, and a specific surface area of 60 m²/g was kneaded in a continuous kneader with the polymer (polymer compound) shown below and dispersed using a sand mill.

Synthesis of Sulfonic Acid-Generating Type Polymer Compound

(1) Synthesis of Monomer (1)

Two hundred (200) ml of acetonitrile, 11 g of hexyl alcohol and 8.8 g of pyridine were put in a three neck flask having a capacity of 500 ml and stirred. Twenty point two (20.2) grams of vinyl benzene sulfonyl chloride was dropwise added thereto with ice-cooling. After completion of dropwise addition, the solution was stirred at room temperature for 2 hours, and then poured into 1 liter of water and extracted with ethyl acetate. The extract was dried over magnesium sulfate and a solvent was distilled off under reduced pressure, and then refined by silica gel column chromatography, thereby exemplified compound Monomer (1) was obtained. Calculated values of elemental analysis were C: 63.13%, H: 6.81 %, and measured values were C: 63.01%, H: 6.85%.

(2) Synthesis of Sulfonic Acid-Generating Type Polymer

Compound (1)

Twenty (20) grams of Monomer (1) and 4.0 g of methyl ethyl ketone were put in a three neck flask having a capacity of 200 ml, and 0.25 g of azobisdimethylvaleronitrile was added thereto under a nitrogen atmosphere at 65° C. The solution was stirred for 5 hours with maintaining the temperature at 65° C., and then a solvent was distilled off under reduced pressure to thereby obtain a solid product. The obtained polymer was found to have a weight average molecular weight of 10,400 by GPC (gel permeation chromatography) (polystyrene standard).

An aluminum plate having a thickness of 0.30 mm (material 1050 defined by JIS H4000: 88) was washed with trichloroethylene and degreased, and then the surface of the plate was subjected to graining with a nylon brush and a pumicestone suspension of 400 mesh, and then thoroughly washed with water. Etching was performed by immersing this plate in a 25% aqueous solution of sodium hydroxide of 45° C. for 9 seconds, washed with water, and then the plate was further immersed in a 2% HNO₃ solution for 20 seconds and washed with water. The weight of etching of the surface which was subjected to graining was about 3 g/m². A direct current anodic oxidation film was formed on this plate with 7% H₂SO₄ solution as an electrolytic solution and at a current density of 15 A/dm³, and then the plate was washed with water and dried.

Eight kinds of Solutions [A-1] to [A-8] were prepared by replacing the sulfonic acid-generating type polymer compounds in the following Solution [A] as shown in Table 1. Each of the thus-obtained solutions was coated on the above-described surface-treated aluminum plate, dried at 100° C. for 2 minutes to obtain Lithographic Printing Plate Precursors [A-1] to [A-8]. The weight of each plate after drying was 1.2 g/m². The transmission density of the coated layer of each sample measured using the density system based upon the system of measurement restricted by the International Standardization Organization IS05-3 was 2.0±0.2.

| Solution [A] | |
|---|---|
| A sulfonic acid-generating type | 1.0 g |
| polymer compound (shown in Table 1) | |
| Iron fine powder | 0.30 g |
| A dye having 1-naphthalene sulfonic acid | 0.05 g |
| as a counter ion of Victoria Pure Blue BOH | |
| Megafac F-177 | 0.06 g |
| (fluorine-based surfactant, produced by | |
| Dainippon Chemicals and Ink Co., Ltd.) | |
| Methyl ethyl ketone | 20 g |
| Methyl alcohol | 7 g |

TABLE 1

| | Lithographic | Sulfonic Acid- |
|---|---|---|
| Example | Printing Plate | Generating Type |
| No. | Precursor | Polymer Compound |
| Example I-1 | [A-1] | (1) |
| Example I-2 | [A-2] | (2) |
| Example I-3 | [A-3] | (3) |
| Example I-4 | [A-4] | (4) |
| Example I-5 | [A-5] | (11) |
| Example I-6 | [A-6] | (8) |
| Example I-7 | [A-7] | (9) |
| Example I-8 | [A-8] | (10) |
| Comparative | [A′-1] | (1) |
| Example I-1 | | |

Note:
γ-Iron oxide was used in [A′-1] in Comparative Example I-1.

Each of the obtained Lithographic Printing Plate Precursors [A-1] to [A-8] was exposed by a YAG laser emitting infrared rays of wavelength of 1,064 nm. After exposure, printing was conducted using Hidel KOR-D printing machine without subjecting each plate to heating treatment. Whether the non-image part of the printed matter was smeared or not was observed. The results obtained are shown in Table 2. Excellent printed matters were obtained having no stain (i.e., no smear) in non-image parts according to the present invention.

TABLE 2

| | Lithographic | Smear of |
|---|---|---|
| Example | Printing Plate | Non-Image Part |
| No. | Precursor | by Printing |
| Example I-1 | [A-1] | Absent |
| Example I-2 | [A-2] | Absent |
| Example I-3 | [A-3] | Absent |
| Example I-4 | [A-4] | Absent |
| Example I-5 | [A-5] | Absent |
| Example I-6 | [A-6] | Absent |
| Example I-7 | [A-7] | Absent |
| Example I-8 | [A-8] | Absent |
| Comparative | [A′-1] | Present |
| Example I-1 | | |

Note:
γ-Iron oxide was used in [A′-1] in Comparative Example I-1.

### COMPARATIVE EXAMPLE I-1

Comparative Lithographic Printing Plate Precursors [A′-1] to [A′-8] were prepared by the same manner as the preparation of [A-1] to [A-8] except for using ferrite (γ-iron oxide, Fe₂O₃) in place of iron fine powders. The transmission density of each sample was 2.0±0.2. Since the results of [A′-1] to [A′-8] were all the same, only the result of [A′-1] is shown in Table 2.

### EXAMPLE II-1

The following compositions were put in a paint shaker (manufactured by Toyo Seiki Co., Ltd.) together with glass beads and dispersed for 60 minutes, and then glass beads were filtered, thereby a dispersion was obtained.

| | |
|---|---|
| Iron fine particle powder | 50 g |
| Titanium oxide sol (30% solution) STS-01 | 167 g |
| (manufactured by Ishihara Sangyo Kaisha Ltd.) | |
| Tetramethoxysilane (manufactured by | 50 g |
| Shin-Etsu Chemical Co., Ltd.) | |
| Concentrated hydrochloric acid | 0.5 g |
| (manufactured by Wako Pure Chemical | |
| Industries Ltd.) | |
| Ethanol | 783 g |
| Water | 117 g |

The above-prepared coating solution was coated on a PET support having a thickness of 188 μm using a wire bar coater in coating weight of 1 g/m², and then dried at 100° C. for 10 minutes, thereby a lithographic printing plate precursor was obtained.

Iron Fine Particle Powder

Fe/Co/Al/Y ratio: 100/20/5/5

Particle size:

Long axis length: 0.1 μm

Short axis length: 0.02 μm

Specific surface area: 60 m²/g

Two microliters of distilled water was put on the surface of the lithographic printing plate precursor, the surface contact angle measured after 30 seconds using a surface contact meter (CA-D, a product of Kyowa Kaimen Kagaku Co., Ltd.) was 10° or less.

The above lithographic printing plate precursor was image-exposed using PEARL setter (a product of Presstek Corp., an infrared laser having transmitting wavelength of 908 nm, output: 1.2 W) at main scanning rate of 2 m/sec.

The contact angle with water of the image part (laser-exposed part) of the obtained lithographic printing plate was 80°. That of the non-image part (unexposed part) remained 10° C. or less as it was.

After laser-exposure, the printing plate was set on a lithographic printing machine without subjecting the plate to any post-treatment and printing was performed. After 1,000 sheets was printed, a background stain-free clear printed matter could be produced. The printing machine used was Ryobi 3200, the fountain solution was 100-time diluted solution of EU-3, and the ink was F gloss Japanese black ink.

### COMPARATIVE EXAMPLE II-1

A lithographic printing plate precursor was prepared in the same manner as in Example II-1 except that the iron fine particle powder was not added. Two microliters of distilled water was put on the surface of the lithographic printing plate precursor, the surface contact angle measured after30 seconds using a surface contact meter (CA-D, a product of Kyowa Kaimen Kagaku Co., Ltd.) was 10° or less.

The above lithographic printing plate precursor was image-exposed using PEARL setter (a product of Presstek Corp., an infrared laser having transmitting wavelength of 908 nm, output: 1.2 W) at main scanning rate of 2 m/sec.

When the contact angle with water of the image part (laser-exposed part) of the obtained lithographic printing plate was measured, no changed was observed, i.e., 10° or less. That of the non-image part (unexposed part) remained 10° C. or less as it was.

After laser-exposure, the printing plate was set on a lithographic printing machine without subjecting the plate to any post-treatment and printing was performed. Ink did not adhere to the image part.

### COMPARATIVE EXAMPLE II-2

A lithographic printing plate precursor was prepared in the same manner as in Example II-1 except for using carbon black in place of the iron fine particle powder. Two microliters of distilled water was put on the surface of the lithographic printing plate precursor, the surface contact angle measured after 30 seconds using a surface contact meter (CA-D, a product of Kyowa Kaimen Kagaku Co., Ltd.) was 20°.

The above lithographic printing plate precursor was image-exposed using PEARL setter (a product of Presstek Corp., an infrared laser having transmitting wavelength of 908 nm, output: 1.2 W) at main scanning rate of 2 m/sec.

The contact angle with water of the image part (laser-exposed part) of the obtained lithographic printing plate was 70°. That of the non-image part (unexposed part) remained 10° C. or less as it was.

After laser-exposure, the printing plate was set on a lithographic printing machine without subjecting the plate to any post-treatment and printing was performed. About 100 sheets of stain-free clear printed matters could be obtained from the start of printing, but when 1,000 sheets were printed, stain had been already generated.

### EFFECT OF THE INVENTION

The present invention can provide a lithographic printing plate precursor of high sensitivity by heating or utilizing the heat energy generated by a self-exothermic reaction caused by light/heat conversion. As one example, a lithographic printing plate of high sensitivity can be directly obtained after exposure by combining a polymer compound which generates a sulfonic acid by heating with the above-described fine powder having a self-exothermic reaction function. According to the present invention, a lithographic printing plate precursor capable of making a printing plate directly from digital data can be obtained by irradiation of laser beams radiating radiant rays such as infrared rays, or using various thermal heads of a simple and compact heat-sensitive printer such as a word processor, or a heat-sensitive facsimile.

Further, printing plate precursors having higher sensitivity and generating no stain (i.e., no smear) can be obtained by using polymers having a secondary sulfonate structure as the sulfonic acid-generating type polymer compound of the present invention, as well as the stability as the image-forming material is improved.

While the invention has been described in detail and with reference to specific examples thereof, it will be apparent to one skilled in the art that various changes and modifications can be made therein without departing from the spirit and scope thereof.

What is claimed is:

1. A radiant ray-sensitive lithographic printing plate precursor which comprises (a) material or material series which absorbs radiant rays, converts the absorbed radiant rays to heat, and enters into a self-exothermic reaction by the heat, and (b) material or material series which causes a chemical change or a physical change by the reaction heat generated as a result of the self-exothermic reaction.

2. The radiant ray-sensitive lithographic printing plate precursor as claimed in claim 1, wherein the material or the material series which absorbs radiant rays, converts the absorbed radiant rays to heat, and enters into a self-exothermic reaction by the heat is a metal powder or a metal compound powder.

3. A radiant ray-sensitive lithographic printing plate precursor which comprises a support having provided thereon an image-recording layer containing (a) a material or a material series which absorbs radiant rays, converts the absorbed radiant rays to heat, and enters into a self-exothermic reaction by the heat, and (b) a resin having a siloxane bond and a silanol group.

4. The radiant ray-sensitive lithographic printing plate precursor as claimed in claim 3, wherein said support is hydrophobic.

5. The radiant ray-sensitive lithographic printing plate precursor as claimed in claim 3, wherein said material or material series which absorbs radiant rays, converts the absorbed radiant rays to heat, and enters into a self-exothermic reaction by the heat is metal or a metal compound, and said image-recording layer further contains anatase-type titanium oxide fine particles.

6. The radiant ray-sensitive lithographic printing plate precursor as claimed in claim 1, wherein the chemical change or the physical change caused by the reaction heat generated as a result of the self-exothermic reaction is the change from hydrophobicity to hydrophilicity.

7. The radiant ray-sensitive lithographic printing plate precursor as claimed in claim 1, wherein the material or the material series which causes the chemical change or the physical change by the reaction heat generated as a result of the self-exothermic reaction is a polymer compound having a functional group which generates a sulfonic acid by heating.

8. The radiant ray-sensitive lithographic printing plate precursor as claimed in claim 7, wherein the functional group which generates a sulfonic acid by heating is at least one compound represented by formula (1), (2) or (3): 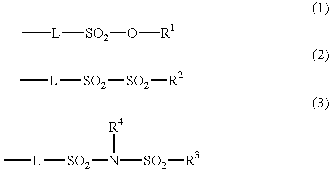
wherein L represents an organic group comprising polyvalent nonmetal atoms necessary for linking a functional group represented by formula (1), (2) or (3) to the polymer skeleton; R¹ represents a substituted or unsubstituted aryl group, a substituted or unsubstituted alkyl group, or a cyclic imido group; R²and R³ each represents a substituted or unsubstituted aryl group, or a substituted or unsubstituted alkyl group; R⁴ represents a substituted or unsubstituted aryl group, a substituted or unsubstituted alkyl group, or —SO₂—R⁵; and R⁵ represents a substituted or unsubstituted aryl group, or a substituted or unsubstituted alkyl group.

9. The radiant ray-sensitive lithographic printing plate precursor as claimed in claim 8, wherein R¹ of the functional group represented by formula (1) which generates a sulfonic acid by heating is a secondary alkyl group represented by formula (4): 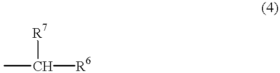
wherein R⁶ and R⁷ each represents a substituted or unsubstituted alkyl group, and R⁶ and R⁷ may form a ring together with the secondary carbon atom (CH) to which they are bonded.

10. The radiant ray-sensitive lithographic printing plate precursor as claimed in claim 9, wherein the secondary alkyl group represented by formula (4) is a secondary alkyl group represented by at least one formula selected from the group consisting of the following formulae:

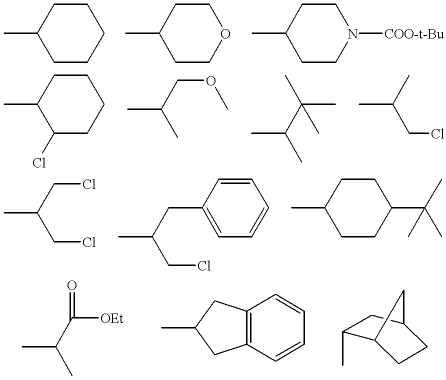

11. A lithographic printing method which comprises conducting image recording by imagewise irradiation of radiant rays or imagewise heat transfer by means of a thermal head on the radiant ray-sensitive lithographic printing plate precursor which comprises (a) material or material series which absorbs radiant rays, converts the absorbed radiant rays to heat, and enters into a self-exothermic reaction by the heat, and (b) material or material series which causes a chemical change or a physical change by the reaction heat generated as a result of the self-exothermic reaction, setting this image recorded plate on a lithographic printing machine, and printing on without subjecting the plate to a wet development process.
